(19) United States
(12) Patent Application Publication
(10) Pub. No.: US 2005/0156651 A1
(43) Pub. Date: Jul. 21, 2005

(54) RS-232 transmitter apparatus

(76) Inventor: Jeong-kee Park, Seoul-si (KR)

Correspondence Address: STANZIONE & KIM, LLP, 1740 N STREET, N.W., FIRST FLOOR, WASHINGTON, DC, 20036, US

(21) Appl. No.: 10/934,498

(22) Filed: Sep. 7, 2004

(30) Foreign Application Priority Data
Jan. 17, 2004 (KR) 2004-3539

(51) Int. Cl. H03D 3/00

(52) U.S. Cl. 327/333

(57) ABSTRACT

An RS-232 transmitter apparatus includes first and second power supplies to respectively supply a first voltage and a second voltage which are based on the RS-232 standard and are different from each other; an input terminal to receive a signal from an external source; and a switching part to select the first power supply or the second power supply according to levels of the signal inputted through the input terminal so as to supply one of the first voltage and the second voltage. With this configuration, the present inputted through the input terminal provides an RS-232 transmitter apparatus which can perform RS-232 communication without an RS-232 transmitter IC including a charge pump, thereby reducing material cost.

### CROSS-REFERENCE TO RELATED APPLICATIONS

This application claims the benefit of Korean Patent Application No. 2004-3539, filed Jan. 17, 2004, in the Korean Intellectual Property Office, the disclosure of which is incorporated herein by reference.

### BACKGROUND OF THE INVENTION

1. Field of the Invention

The present general inventive concept relates to an RS-232 transmitter apparatus, and more particularly, to an RS-232 transmitter apparatus which can perform RS-232 communication without an RS-232 transmitter integrated circuit (IC), thereby reducing material cost.

2. Description of the Related Art

Most of a digital circuit system is operated by a voltage level of 5V, but RS-232 communication requires a voltage of +5V˜+15V and −15V ˜5V, so that an RS-232 transmitter integrated circuit (IC) comprising a charge pump is needed for the RS-232 communication.

FIG. 1 is a schematic circuit diagram of a conventional RS-232 transmitter IC, and FIGS. 2A through 2D are circuit diagrams of a charge pump of FIG. 1. Here, the charge pump of FIGS. 2A through 2D is illustrated with reference to an SP207E IC made by Sipex Corporation.

As shown therein, the conventional RS-232 transmitter IC 100 receives input of a transistor-transistor logic (TTL) level or a complementary metal-oxide-semiconductor (CMOS) level, and outputs an RS-232 voltage level different according to the input logic levels through the charge pump. Here, a TTL/CMOS input terminal and an RS-232 output terminal may be plurally provided, respectively.

In the SP207E IC, the charge pump uses a four-phase voltage shifting technique to get a voltage of ±10V. As shown in FIGS. 2A through 2D, the charge pump operates according to phases, as follows.

In a first phase, as shown in FIG. 2A, positive terminals of capacitors “C1” 122 and “C2” 124 are being charged with a voltage of +5V. When the positive terminal of the capacitor “C1” is grounded by switching a switch 132, the charged voltage of a negative terminal of the capacitor “C1” is applied to a negative terminal of the capacitor “C2”. At this time, the positive terminal of the capacitor “C2” is being connected to a voltage of +5, so that potential difference of the capacitor “C2” is 10V.

In a second phase, as shown in FIG. 2B, the negative terminal of the capacitor “C2” is connected to a negative terminal of a capacitor “C3” 128 by switching a switch 154, and the positive terminal of the capacitor “C2” is grounded by switching a switch 142. Then, the potential difference of −10V is applied to the capacitor “C3”, and at the same time, the positive terminal of the capacitor “C1” is connected to the voltage of +5V by switching the switch 132 and the negative terminal of the capacitor “C1” is grounded by switching a switch 134.

In a third phase, as shown in FIG. 2C, the operation of the charge pump is identical with the operation in the first phase. Likewise, the voltage applied to the capacitor “C1” is used to make the negative terminal of the capacitor “C1” be charged with the voltage of −5V. Then, the voltage of −5V is applied to the negative terminal of the capacitor “C2”. At this time, the positive terminal of the capacitor “C2” is being connected to the voltage of +5V, so that the potential difference of the capacitor “C2” is 10V.

In a fourth phase, as shown in FIG. 2D, the negative terminal of the capacitor “C2” is grounded, and the potential difference of 10V in the capacitor “C2” is applied to a capacitor “C4” 126. At the same time, the positive terminal of the capacitor “C1” is connected to the voltage of +5V by switching the switch 132 and the negative terminal of the capacitor “C1” is grounded by switching a switch 134, thereby returning to the first phase and repeating the foregoing cycle.

Thus, such RS-232 transmitter IC 100 outputs −10V and +10V through the foregoing cycle when a high level and a low level are inputted, respectively.

However, the conventional RS-232 transmitter IC 100 employs the charge pump to output the RS-232 level whenever the TTL/CMOS levels are inputted, so that material cost is increased.

### SUMMARY OF THE INVENTION

Accordingly, it is an aspect of the present general inventive concept to provide an RS-232 transmitter apparatus which can perform RS-232 communication without an RS-232 transmitter IC having a charge pump, thereby reducing material cost.

Additional aspects and/or advantages of the general inventive concept will be set forth in part in the description which follows and, in part, will be obvious from the description, or may be learned by practice of the general inventive concept.

The foregoing and/or other aspects and advantages of the present general inventive concept are achieved by providing an RS-232 transmitter apparatus including first and second power supplies to respectively supply a first voltage and a second voltage which are based on the RS-232 standard and are different from each other; an input terminal to receive a signal from an external source; and a switching part to select the first power supply or the second power supply according to levels of the signal inputted through the input terminal so as to output one of the first voltage and the second voltage.

According to an aspect of the general inventive concept, the first voltage ranges from +5V to +15V, and the second voltage ranges from −15V to −5V, and the switching part selects the first voltage to be outputted when the level of the signal inputted through the input terminal is low, and selects the second voltage to be outputted when the level of the signal inputted through the input terminal is high.

According to an aspect of the present general inventive concept, the RS-232 transmitter apparatus may further include an output terminal to output the first voltage or the second voltage selected by the switching part, wherein the switching part may include a first switch to be turned on/off according to the levels of the signal inputted through the input terminal, a second switch allowing the first voltage of the first power supply to be supplied when the first switch is turned off; a third switch allowing the first voltage to be supplied from the second switch to the output terminal according to the levels of the signal inputted through the input terminal; and a current passage through which the second voltage is supplied from the second power supply to the output terminal when the first voltage is not supplied from the third switch.

According to an aspect of the present general inventive concept, the first switch is turned off and the third switch allows the first voltage to be outputted through the output terminal when the level of the signal inputted through the input terminal is low.

### BRIEF DESCRIPTION OF THE DRAWINGS

These and other aspects and advantages of the present general inventive concept will become apparent and more readily appreciated from the following description of the embodiments, taken in conjunction with the accompany drawings of which:

FIG. 1 is a schematic circuit diagram of a conventional RS-232 transmitter IC;

FIGS. 2A through 2D are circuit diagrams of a charge pump of FIG. 1;

FIG. 3 is a circuit diagram of an RS-232 transmitter apparatus according to an embodiment of the present invention; and

FIG. 4 illustrates waveforms showing performance of the RS-232 transmitter apparatus of FIG. 3 as compared with the conventional RS-232 transmitter IC.

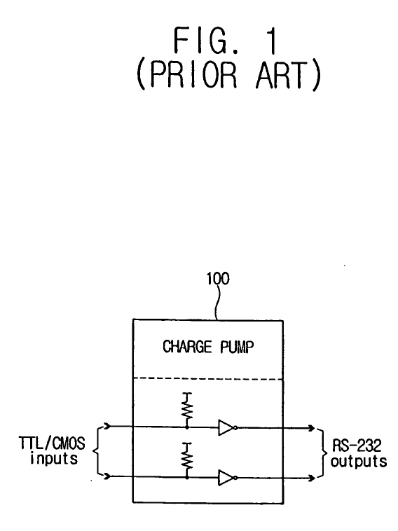

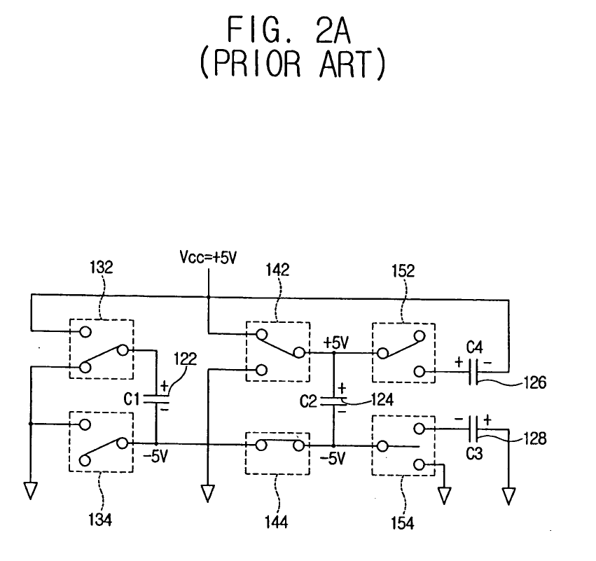

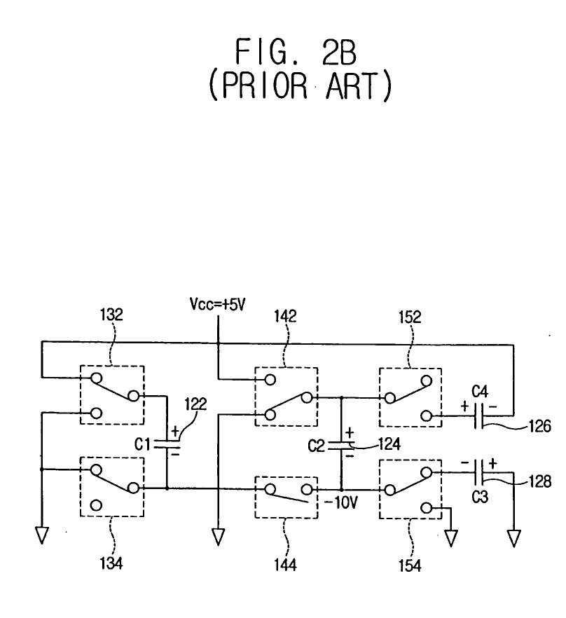

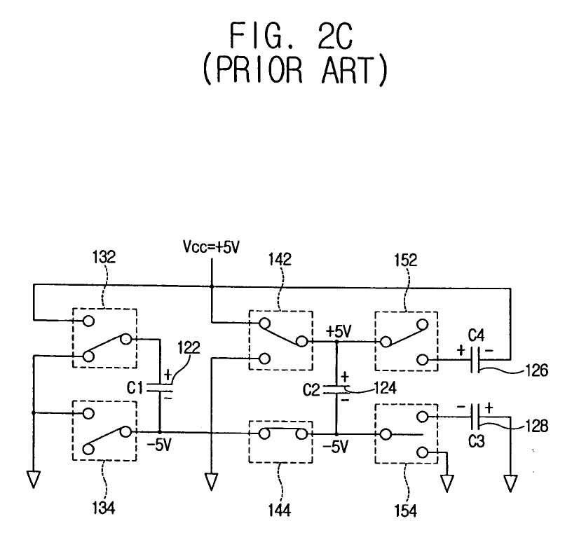

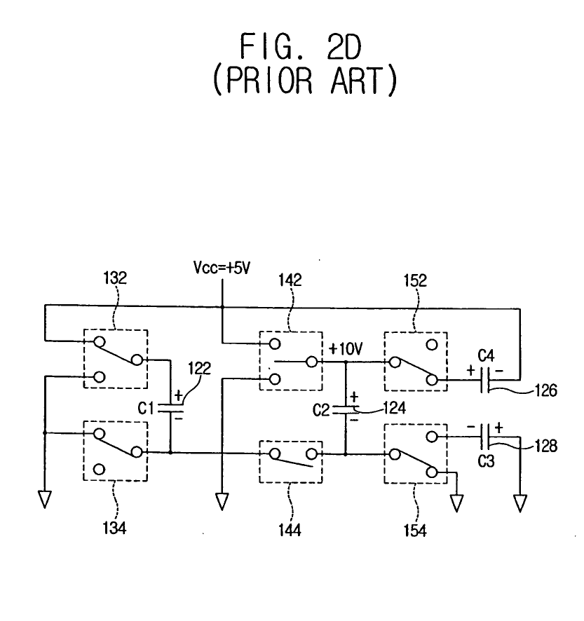

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to like elements throughout. The embodiments are described below in order to explain the present invention by referring to the figures.

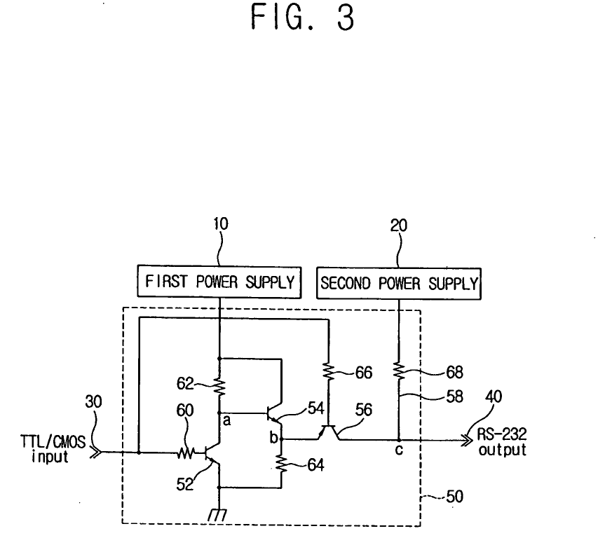

FIG. 3 is a circuit diagram of an RS-232 transmitter apparatus according to an embodiment of the present general inventive concept. As shown in FIG. 3, the RS-232 transmitter apparatus includes first and second power supplies 10 and 20 to respectively supply a first voltage and a second voltage which are based on the RS-232 standard and are different from each other; an input terminal 30 to receive a TTL/CMOS signal from an external source; a switching part 50 to select the first power supply 10 or the second power supply 20 according to a level of the signal inputted through the input terminal 30 so as to supply one of the first voltage and the second voltage; and an output terminal 40 to output the first voltage or the second voltage selected by the switching part 50.

Here, according to the RS-232 standard, the first voltage ranges from +5V to +15V as a plus voltage level, and the second voltage ranges from −15V to −5V as a minus voltage level.

The switching part 50 selects the first voltage as the plus voltage level based on the RS-232 standard to be outputted in the case where a level of the signal inputted through the input terminal 30 is low, and selects the second voltage as the minus voltage level based on the RS-232 standard to be outputted when the level of the input signal is high.

Such switching part 50 may include a first switch 52 to be turned on when the high level signal is inputted through the input terminal 30 and be turned off when the low level signal is inputted through the input terminal 30; a second switch 54 allowing the first voltage of the first power supply 10 to be supplied when the first switch 52 is turned off; a third switch 56 allowing the first voltage to be supplied from the second switch 54 to the output terminal 40 when the low level signal is inputted through the input terminal 30; and a current passage 58 through which the second voltage is supplied from the second power supply 20 to the output terminal 40 when the first voltage is not supplied from the third switch 56. According to an embodiment of the general inventive concept, the first and second switches 52 and 54 may be a type of an NPN (or N-channel) transistor, and the third switch 56 may be a type of a PNP (or P-channel) transistor.

When the TTL/CMOS signal inputted from the input terminal 30 has a low level, the first switch 52 is turned off, and a voltage applied to a node “a” becomes high due to the first voltage supplied from the first power supply 10. Then, the high level signal of the node “a” causes the second switch 54 to be turned on, and a voltage applied to a node “b” becomes the first voltage.

Further, the third switch 56 allows the first voltage applied to the node “b” to be supplied to a node “c” as the low level signal is inputted through the input terminal 30. Thus, the first voltage is outputted as the RS-232 plus voltage level through the output terminal 40.

In contrast, when the TTL/CMOS signal inputted from the input terminal 30 has a high level, the first switch 52 is turned on, and the voltage applied to the node “a” becomes low. Then, the low level signal of the node “a” causes the second switch 54 to be turned off, and the voltage applied to the node “b” becomes low.

Further, the third switch 56 interrupts the voltage supplied from the node “b” to the node “c” as the high level signal is inputted through the input terminal 30. Thus, the second voltage is outputted as the RS-232 minus voltage level from the second power supply 20 through the output terminal 40.

Thus, the RS-232 transmitter apparatus according to an embodiment of the present general inventive concept can output the RS-232 level without a conventional RS-232 transmitter IC including a charge pump.

In FIG. 3, reference numerals 60, 62, 64, 66 and 68 indicate resistors.

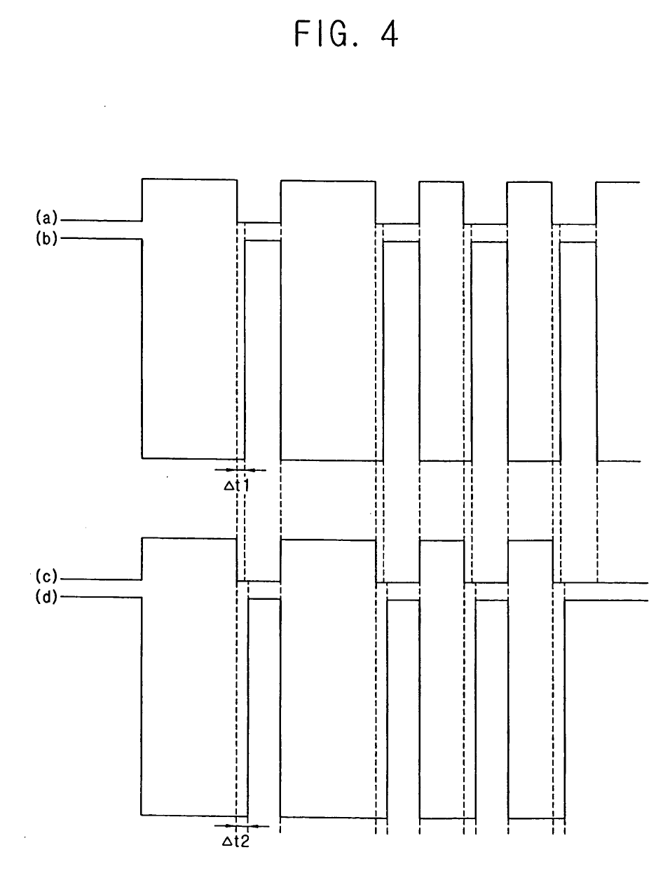

With this configuration, performance of the RS-232 transmitter apparatus according to an embodiment of the present general inventive concept as compared with the conventional RS-232 transmitter IC is illustrated in FIG. 4.

In FIG. 4, (a) and (b) illustrate the TTL/CMOS level input and the RS-232 level output of the present RS-232 transmitter apparatus, and (c) and (d) illustrate the TTL/CMOS level input and the RS-232 level output of the conventional RS-232 transmitter IC.

Comparing (b) with (d), a rising time “Δt1” of the present RS-232 transmitter apparatus is shorter than a rising time “Δt2” of the conventional RS-232 transmitter IC. This means that RS-232 communication speed of the present general inventive concept RS-232 transmitter apparatus is faster than that of the conventional RS-232 transmitter IC, and thus the RS-232 transmitter apparatus according to the present general inventive concept improves the RS-232 communication speed.

Meanwhile, alternatively, the node “b” related to the third switch may be directly connected to the first power supply, thus eliminating the need for the first switch and the second switch.

As described above, there are provided the first and second power supplies instead of the charge pump so as to output the RS-232 level, and one of the first voltage and the second voltage is selectively outputted according to the high/low levels of the signal inputted from the external source, so that the RS-232 transmitter apparatus according to the present invention can perform the RS-232 communication without an RS-232 transmitter IC including the charge pump, thereby reducing material cost.

As described above, the present general inventive concept provides an RS-232 transmitter apparatus which can perform RS-232 communication without an RS-232 transmitter IC including a charge pump, thereby reducing material cost.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

1. An RS-232 transmitter apparatus comprising:
first and second power supplies to respectively supply a first voltage and a second voltage which are based on an RS-232 standard and are different from each other;
an input terminal to receive a signal from an external source; and
a switching part to select the first power supply or the second power supply according to levels of the signal inputted through the input terminal so as to supply one of the first voltage and the second voltage.

2. The RS-232 transmitter apparatus according to claim 1, wherein the first voltage ranges from +5V to +15V, and the second voltage ranges from −15V to −5V, and
the switching part selects the first voltage to be outputted when the level of the signal inputted through the input terminal is low, and selects the second voltage to be outputted when the level of the signal inputted through the input terminal is high.

3. The RS-232 transmitter apparatus according to claim 2, further comprising an output terminal to output the first voltage or the second voltage selected by the switching part.

4. The RS-232 transmitter apparatus according to claim 3, wherein the first switch is turned off and the third switch allows the first voltage to be outputted through the output terminal when the level of the signal inputted through the input terminal is low.

5. The RS-232 transmitter apparatus according to claim 3, wherein the switching part comprises:
a first switch to be turned on/off according to the levels of the signal inputted through the input terminal;
a second switch allowing the first voltage of the first power supply to be supplied when the first switch is turned off;
a third switch allowing the first voltage to be supplied from the second switch to the output terminal according to the levels of the signal is inputted through the input terminal; and
a current passage through which the second voltage is supplied from the second power supply to the output terminal when the first voltage is not supplied from the third switch.

6. The RS-232 transmitter apparatus according to claim 3, wherein the switching part comprises:
a switch allowing the first voltage to be supplied to the output terminal according to the levels of the signal inputted through the input terminal; and
a current passage through which the second voltage is supplied from the second power supply to the output terminal when the first voltage is not supplied from the switch.

7. An RS-232 transmitter apparatus comprising:
first and second power supplies to respectively supply a first voltage and a second voltage which are based on an RS-232 standard and are different from each other; and
a switching unit to selectively output the first power supply or the second power supply.

8. The RS-232 transmitter apparatus of claim 7, wherein the switch unit selectively outputs either the first or second power supply according to levels of a signal detected from an external source.

9. The RS-232 transmitter apparatus according to claim 7, wherein the first voltage ranges from +5V to +15V, and the second voltage ranges from −15V to −5V.

10. The RS-232 transmitter apparatus according to claim 8, wherein the switching unit selects the first voltage to be outputted when the level of the signal detected is low, and selects the second voltage to be outputted when the level of the signal detected is high.

11. The RS-232 transmitter apparatus according to claim 7, wherein the switching part comprises:
a first switch to be turned on or off according to the levels of the detected signal;
a second switch allowing the first voltage of the first power supply to be supplied when the first switch is turned off;
a third switch allowing the first voltage to be output from the second switch according to the levels of the detected signal; and
a current passage through which the second voltage is supplied from the second power supply to be output when the first voltage is not supplied from the third switch.

12. The RS-232 transmitter apparatus according to claim 7, wherein the switching part comprises:
a switch allowing the first voltage to be output according to the levels of the detected signal; and
a current passage through which the second voltage is supplied from the second power supply to be output when the first voltage is not supplied from the switch.
